(19) United States
(12) Patent Application Publication
(10) Pub. No.: US 2002/0146857 A1
(43) Pub. Date: Oct. 10, 2002

(54) Method for manufacturing semiconductor laser

(76) Inventor: Jun Ichihara, Kyoto-shi (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/116,101

(22) Filed: Apr. 5, 2002

(30) Foreign Application Priority Data
Apr. 6, 2001 (JP) 2001-108668

(51) Int. Cl. H01L 21/00

(52) U.S. Cl. 438/47; 438/29

(57) ABSTRACT

First, an active layer (3) of quantum well structure made of a semiconductor material is sandwiched by n-type and p-type clad layers (2, 4) made of a semiconductor material larger in band gap than the semiconductor of active layer, and a semiconductor laminate wafer (10) is formed so as to compose a laser resonator. The wafer is cleaved into bar form so as to expose end faces of the resonator. Further a thin film (11) containing a dopant is formed on at least one of the end faces of the resonator, and then end face coat films (12, 13) are formed. Thereafter it is heated to diffuse the dopant on the end face of the resonator. As a result, the band gap can be increased only on the resonator end face securely, and therefore this manufacturing method realizes a semiconductor laser having a window structure so as not to absorb light at the end face and capable of preventing deterioration of end face due to surface re-bonding.

### FIELD OF THE INVENTION

The present invention relates to a method for manufacturing a high output semiconductor laser suited to light source for optical information terminal, applied measurement, optical communication, or the like. More particularly the present invention relates to a manufacturing method of a semiconductor laser capable of suppressing breakdown of end face due to catastrophic optical damage (COD) in a high output semiconductor laser.

### BACKGROUND OF THE INVENTION

As a signal amplifying system in optical fiber communications, for example, a method of transmitting by amplifying directly by a fiber amplifier is known, and development of laser for exciting fiber amplifier of high output of about 250 mW is being demanded. In such high output semiconductor laser, a particularly high reliability is required, but as the operation time becomes longer, the reliability is lowered due to internal deterioration, and catastrophic optical damage occurs, and the end face breakdown level is lowered, which may lead to a sudden deterioration.

Hitherto, to prevent such catastrophic optical damage, various methods have been attempted, for example, (1) a method of forming a window structure to make light absorption difficult by increasing the band gap at the resonator end side in the active layer of quantum well structure, and (2) a method of scattering away the oxygen or eliminating dangling bond of the resonator end face: that is the surface re-bonding is promoted by oxygen sticking to the resonator end face and dangling bond on the resonator end face, and when the temperature rises due to re-bonding, oxidation is encouraged and light is absorbed more easily, so that the temperature is further raised, and therefore ions of Ar⁺ or the like are injected to the resonator end face to scatter away the oxygen sticking to the surface, or the end face is exposed in vacuum by cleavage or the like, and then while maintaining the same state, a reflective film is formed, or an intermediate layer of amorphous silicon or the like is provided before forming the reflective film, so that dangling bond may be eliminated.

The method of forming the window structure is disclosed, for example, by Nagai et al. in “High output semiconductor laser of 0.98 μm band ridge type window structure” (Japan Society of Electronics, Information and Communication, Shingaku Giho EMD98-34, pp. 43-47, August 1998), and its structural example is shown in FIG. 4, in which an n-type clad layer 22 made of n-type AlGaAs, an active layer 23 of double quantum well structure composed of InGaAs well layer and GaAs barrier layer, and a p-type first clad layer 24a made of p-type AlGaAs are grown on an n-type GaAs substrate 21, Si ions are implanted in the area corresponding to the end face, and further a p-type second clad layer 24b made of p-type AlGaAs, and a contact layer 26 made of p-type GaAs are grown, and a ridge structure as shown in FIG. 4 is formed by etching. Moreover, by cleaving the Si at the ion implanting position, a semiconductor laser of ridge structure as shown in FIG. 4 is formed. At the top of the ridge structure and at the back side of the GaAs substrate 21, a p-side electrode and an n-side electrode are formed respectively, but are not shown in the drawing.

In this structure, Si ions implanted at the end position of the ridge structure are diffused by the temperature elevated by the subsequent growth of semiconductor layer to form a diffusion layer 27, and the double quantum well structure in the active layer at the end face is put in disorder, and the band gap becomes large. As a result, the band gap only at the end side of the active layer increases and does not contribute to oscillation, and the light absorption becomes smaller due to large band gap, thereby preventing temperature elevation and breakdown due to absorption of light particularly at the end face.

As mentioned above, in the semiconductor laser forming the window structure, in the midst of epitaxial growth of semiconductor layer, Si or other ions must be implanted at the position cleaving in the chip, and if the later cleaving position is deviated, if slightly, from the Si ion implanting position, the effect of preventing the end face breakdown is eliminated, and the luminous efficiency is lowered, and the manufacturing yield is lowered.

Besides, by cleaving the wafer in vacuum, coating the cleavage plane with intermediate layer or reflective film in order to eliminate dangling bond is a very difficult work. Or in the method of cleaving in the air atmosphere and removing oxygen from the surface by ion irradiation or the like, the active layer is damaged by ion irradiation, and the luminous efficiency is lowered.

### SUMMARY OF THE INVENTION

The present invention is directed to solve these problems, and it is hence an object of the present invention is to provide a manufacturing method of semiconductor laser having a window structure, capable of eliminating absorption of light at the end face, by increasing the band gap only at the resonator end face securely.

It is another object of the present invention to provide a manufacturing method of semiconductor laser capable of preventing deterioration of end face due to surface re-bonding, by removing impurities such as oxygen sticking to the end face in a simple method without cleaving in vacuum atmosphere or irradiating with ion.

A method for manufacturing a semiconductor laser of the present invention includes the steps of; forming a semiconductor laminate wafer to compose a laser resonator by sandwiching an active layer of quantum well structure made of a semiconductor material with n-type and p-type clad layers made of a semiconductor material of a larger band gap than the semiconductor material of the active layer, cleaving the wafer into bar form so as to expose end faces of the resonator, forming a thin film containing a dopant on at least one of the end faces of the resonator, forming end face coat films on the at least one of end faces, and heating to diffuse the dopant into the at least one of end faces.

By employing this method, for example, without positioning strictly cleaving portion with the ion implanted position doped by Si ions as in the related art, for example, after cleaving in the bar form, a thin film containing the dopant is formed on the cleavage surface by CVD method or the like, and is heated and diffused, so that the impurities can be diffused securely on the end face of the resonator. As the dopant is distributed on the active layer of the quantum well structure, the quantum well structure is put in disorder, and the band gap increases. As a result, the light emitted in the active layer is hardly absorbed on coming to the end face side, thereby avoiding catastrophic optical damage due to concentration of light at the end face and generation of heat.

The thin film containing the dopant may be either p-type or n-type, but a material more likely to be oxidized than the material for composing the active layer or clad layers is preferred because undesired oxygen can be removed by reacting with the oxygen sticking to the surface, while diffusing the impurities by heat treatment. The thin film may be formed by a metal layer of the dopant metal or a compound layer of a metal-rich fluoride, a metal-rich nitride, a metal-rich oxide or a metal-rich carbide, each of which contains the excessive metal stoichiometrically. As such materials, for example, Mg or Mg-rich magnesium fluoride or Mg-rich magnesium oxide is preferred because it is more likely to be oxidized than Al in the semiconductor material, and other examples include Zn or Zn rich zinc oxide. When forming a metal layer of such metal material as a thin film, if left over after heating process, the upper and lower clad layers may be shorted, when the resonator is formed parallel to the laminate surface, and therefore it is important to form the film very thinly, less than about several atomic layers.

The heat treatment is preferably heating only on the thin film and on the end face side where the end face coat films are provided, and it is preferred to process in a short time by heating the surface, for example, by using a lamp. Moreover, since the heat treatment is done after forming the laminate structure of the semiconductor layer and upper and lower electrodes, due caution is needed so as not to raise the entire temperature too much or not to change the characteristic as the element. From such viewpoint, it is preferred to uses the light of the wavelength having a smaller band gap than that of the semiconductor substrate and clad layers, and a band gap larger than that of the active layer so that the active layer absorbs the light of the heat rays of lamp heating and the semiconductor substrate does not absorb much. The light of the desired wavelength can be obtained by using a filter. Further, in order not to raise the entire temperature too much, it is preferred to heat by the lamp intermittently.

### BRIEF DESCRIPTION OF THE DRAWINGS

FIG. 1A to FIG. 1C are explanatory views showing steps of manufacturing method of the present invention;

FIG. 2A and FIG. 2B are views showing the band structure of end face near the active layer in a state of growing semiconductor layers and a state after heat treatment according to the present invention;

FIG. 3 is a view showing an example of controlling the wavelength of the light to be radiated in heat treatment according to the present invention; and

FIG. 4 is an explanatory view of an example of forming a window structure of a conventional semiconductor layer.

### DETAILED DESCRIPTION

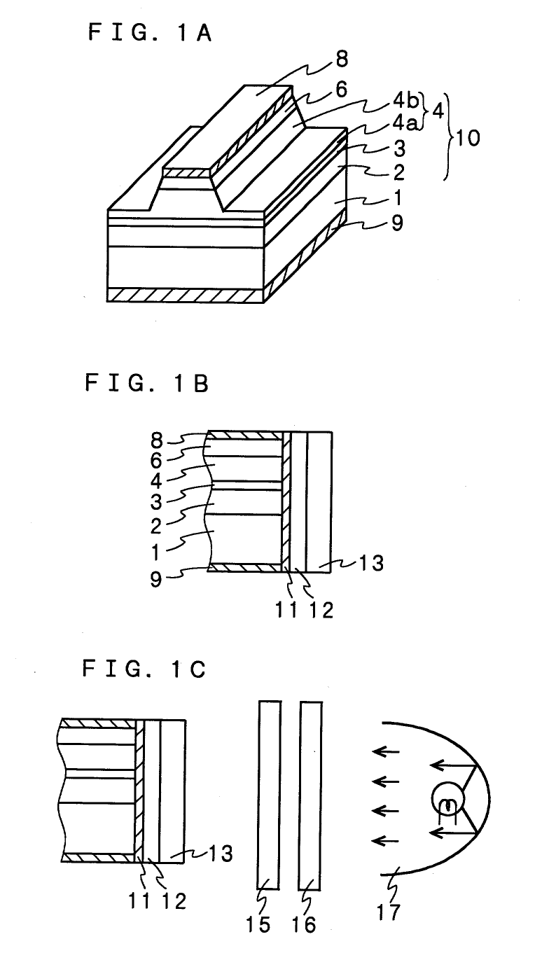

The manufacturing method of a semiconductor laser of the present invention is explained below while referring to FIGS. 1A to 1C which show steps of the process in an embodiment. In the manufacturing method of the semiconductor laser of the present invention, first as shown in FIG. 1A, an active layer 3 of quantum well structure made of semiconductor material is sandwiched by n-type and p-type clad layers 2, 5 made of a semiconductor material of which band gap is larger than that of the active layer 3, and a semiconductor laminate portion 10 (wafer) is formed so as to compose a laser resonator. The wafer is cleaved into bar form so as to expose end faces of the resonator. Then as shown in Fig. 1B, a thin film 11 containing a dopant is formed on at least one of the end faces of the resonator, and end face coat films 12, 13 are formed. Thereafter as shown in FIG. 1C, heat treatment is applied to diffuse the dopant on the end face of the resonator. In FIG. 1B and FIG. 1C, the thickness of the thin film 11 and end face coat films 12, 13 are exaggerated, while the thickness of the substrate 1 is shown in a reduced scale, and the actual thickness relation of the entire structure is not shown correctly.

The semiconductor laminate portion 10 includes, as shown in FIG. 1A which shows a basic perspective explanatory view, a GaAs substrate 1 of, for example, n-type, an n-type clad layer 2 of n-type AlₓGa₁₋ₓAs (0.1≦x≦0.7, for example, x=0.6), a non-doped or n-type or p-type active layer 3 of single or multiple quantum well structure composed of a well layer of In_{y}Ga₁₋As (0.1≦y≦0.3, for example, y=0.2) and a barrier layer of GaAs, a p-type clad layer 4 (a first clad layer 4a and a second clad layer 4b) of p-type AlₓGa₁₋ₓAs, and a contact layer 6 of p-type GaAs, being formed in a double hetero structure of laminated structure. Although not shown, an etching stop layer made of, for example, In_{z}Ga_{1-z}P is provided between the p-type first clad layer 4a and second clad layer 4b, so that the etching may not reach up to the active layer 3 in the case of forming a ridge structure. In this double hetero structure, the material of the active layer 3 is determined by the band gap depending on the desired emission wavelength, and in order to enclose the carrier and the light in the active layer 3, it is sandwiched by the clad layers 2, 4 made of a material larger in the band gap. Therefore, depending on the desired wavelength, instead of AlGaAs compound, other semiconductor such as InGaAlP compound may be used.

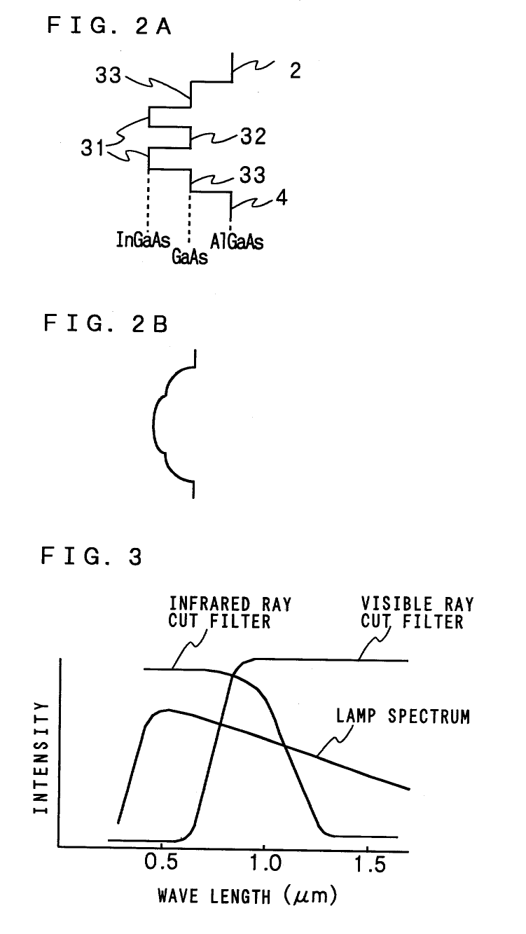

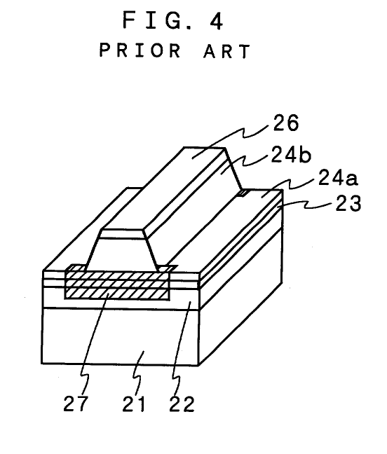

The active layer 3 has, in an epitaxially grown state, a conduction band of well layer 31 made of In_{0.2}Ga_{0.8}As and barrier layer 32 made of GaAs, which is changed in a rectangular form as shown in FIG. 2A which is a band structural view of an example of forming the well layer 31 in two stages (a double quantum well structure). This quantum well structure may be either single quantum well structure (SQW) or multiple quantum well structure (MQW) of three stages or more. Reference numeral 33 is a guide layer made of GaAs, 2 is an n-type clad layer of, for example, Al_{0.6}Ga_{0.4}As, and 4 is a p-type clad layer of the same composition.

After completion of growth of semiconductor laminate portion 10, in order to form a ridge of a emitting portion, the contact layer 6 and p-type clad layer 4b is processed by etching, by dry etching or by using an etchant of H₂SO₄-H₂O₂ compound, with masking. Thereafter, a p-side electrode 8 is formed on the contact layer 6, and an n-side electrode 9 is formed on the back side of the semiconductor substrate 1. Although shown schematically in the view, the p-side electrode 8 is formed by forming an insulating film not shown on the entire surface and forming contact holes on the ridge of the insulating film.

Then, to form a chip from the state of a wafer, first, the wafer is cleaved in a bar form so that the emitting end faces (resonator end faces) may be exposed in a mirror smooth state. As shown in a sectional explanatory view of one end face in FIG. 1B, by using a sputtering apparatus, for example, an Mg thin film 11 is formed by several atomic layer, that is, about 2 to 5 nm in thickness, with the end face of the cleaved bar form upward. Further, by using the sputtering apparatus or the like, an amorphous silicon film 12 is formed successively as an end face coat film in a thickness of 1/(4n) of the emitting light wavelength (n being a refractive index), for example, about 66 nm (n=3.7), and an Al₂O₃ film 13 is formed similarly in a thickness of 1/(4n) of the wavelength, for example, in a thickness of 130 nm (n=1.9), and one set or two or more sets thereof are laminated, and a thin film 11 and end face coat films 12, 13 are formed at both end faces respectively so that the reflectivity of the light emitting side end face (front end face) may be, for example, about 0.5% to 2%, and that the reflectivity of the rear end side may be about 95% to 98%, that is, not to reflect at the front end face as much as possible and reflect as high as possible at the rear end face.

The Mg thin film 11 is provided as a dopant as mentioned below, and also functions to prevent oxidation of the element for composing a semiconductor layer by compounding with the oxygen sticking to the surface. That is, for example, when an element which is more likely to oxidize than Al which is a constituent element of AlGaAs compound is provided, if oxygen sticks to the exposed surface of the end face or there is oxygen oxidizing with Al, by raising the temperature, the Mg effectively oxidizes with the oxygen to eliminate the deterioration by absorbing the light. Therefore, the thin film is preferred to contain a metal stronger in oxidizing power than Al and acting as dopant. By forming the thin film containing an element acting as dopant, by a subsequent process of heat treatment as mentioned below, the band gap of the resonance end face can be increased in a simple method, and a window structure not absorbing light can be formed.

The end face coat films are formed so as to achieve a specified reflectivity in a laminated structure in a thickness of λ/4n (n being a refractive index, X being an emitting light wavelength) same as in the prior art, but in the present invention, since an amorphous silicon film is provided at the Mg thin film side, by bonding with dangling bond of the end face exposed as the Mg thin film is eliminated, its activation can be suppressed, and the spiral of oxidation due to temperature rise can be arrested.

From these points of view, the thin film containing the dopant is not limited to Mg, but may contain Zn or other element. The thin film containing the dopant is not limited a single metal of Mg or Zn, but may include metal-rich fluoride, metal-rich nitride or metal-rich oxide containing much of these metals, for example, Mg-rich magnesium fluoride or Mg-rich magnesium oxide, or Zn-rich zinc oxide.

Later, as shown in FIG. 1C, the films are heated by radiating with a lamp 17 from the end face coat films 12, 13 side. The lamp 17 is used for heating because the formation of laminate portion of the semiconductor layers and electrodes has been already finished, and excessive temperature rise may cause adverse effects on the characteristics of the semiconductor laser or ohmic contact with the electrodes, and therefore the entire temperature should not be elevated too much, and it is enough only when the temperature of the Mg thin film is raised slightly to diffuse in the semiconductor layer or adsorb the nearby oxygen. Accordingly, when heating by the lamp, only a short time of about 0.05 to 1 second is enough, and if heating is insufficient, it is preferred to heat intermittently by the lamp.

Alternatively, in order not to raise the temperature too much, as shown in FIG. 1C, light is emitted by using a visible ray cut filter 15 and an infrared ray cut filter 16, and it is preferred to emit the light at a wavelength to be absorbed by the active layer 3 but not absorbed by the semiconductor substrate 1 or clad layers 2, 4. The wavelength of the passing light when the visible ray cut filter 15 and infrared ray cut filter 16 shown in FIG. 1 (c) are inserted is as shown in FIG. 3, that is, light at wavelength of 0.8 to 1.1 μm is emitted, and the light at this wavelength is hardly absorbed in AlGaAs or GaAs. For example, by emitting the output having a lamp spectrum as shown in FIG. 3 by using a lamp of 16 kW, the Mg thin film and end face coat films formed on the end face of the semiconductor laser were radiated for about 0.5 second, and the Mg diffused by the portion of the thickness of hundreds of nm of the end face, and the oxygen depositing on the surface of the end face was absorbed, and a semiconductor laser free from end face breakdown was obtained. If reduced to the light near a specific wavelength only, two filters are not needed as in the case above, but same effects are obtained by using one band pass filter only.

By depositing the thin film containing the dopant on the resonator end face and diffusing by heat treatment, the rectangular conduction band of quantum well structure is destroyed as shown in the band structural diagram near the active layer at the end face in FIG. 2B, and the quantum well structure no longer exists, and the band gap increases. As a result, the emitting light is not absorbed by the active layer, and catastrophic optical damage can be prevented. Further, by using a material likely to compound with oxygen such as Mg as the dopant, or by containing a material likely to compound with oxygen in the film containing the dopant, the oxygen sticking to the surface of the end face can be easily captured, and therefore without requiring difficult operation such as cleaving in vacuum or ion irradiation, deterioration due to surface re-bonding can be prevented simultaneously with the window forming process.

According to the present invention, by a very simple method, the window structure can be formed by increasing the gap only at the resonator end face securely, and catastrophic optical damage can be prevented. Further, by containing an element more likely to compound with oxygen than the element for composing the semiconductor layer, in the thin film containing the dopant, the oxygen sticking or compounding on the resonator end face can be gettered, and catastrophic optical damage due to surface re-bonding can be also prevented. As a result, even in the semiconductor laser of high output, a semiconductor laser of a very high reliability is obtained, and the reliability of the exciting light source of fiber amplifier or the like can be enhanced.

Although preferred examples have been described in some detail it is to be understood that certain changes can be made by those skilled in the art without departing from the spirit and scope of the invention as defined by the appended claims.

What is claimed is:

1. A method for manufacturing a semiconductor laser comprising the steps of:
forming a semiconductor laminate wafer to compose a laser resonator by sandwiching an active layer of quantum well structure made of a semiconductor material with n-type and p-type clad layers made of a semiconductor material of a larger band gap than said semiconductor material of active layer;
cleaving said wafer into bar form so as to expose end faces of said resonator;
forming a thin film containing a dopant on at least one of said end faces of said resonator;
forming end face coat films on said at least one of end faces; and
heating to diffuse said dopant into said at least one of end faces.

2. The manufacturing method of claim 1, wherein said thin film containing the dopant is made of a material containing a metal which is more likely to oxidize than the material for composing said active layer and said clad layers.

3. The manufacturing method of claim 2, wherein said thin film is formed by a metal layer of said metal.

4. The manufacturing method of claim 2, wherein said thin film is composed of at least one of a metal-rich fluoride, a metal-rich nitride a metal-rich oxide and a metal-rich carbide which are excess in a metal content stoichiometrically.

5. The manufacturing method of claim 2, wherein said metal is Mg.

6. The manufacturing method of claim 1, wherein said thin film is formed in a thickness of several atomic layer or less.

7. The manufacturing method of claim 1, wherein said heating is conducted by using a lamp to radiate only an end face part on which said thin film and said end face coat films are provided.

8. The manufacturing method of claim 7, wherein said heating by said lamp is conducted by using a light at a wavelength having a band gap smaller than the band gap of said semiconductor substrate and said clad layers, and larger than the band gap of said active layer.

9. The manufacturing method of claim 8, wherein said wavelength of the light is 0.8 to 1.1 μm.

10. The manufacturing method of claim 8, wherein the light from said lamp is radiated by limiting to the light of said wavelength by using a wavelength filter.

11. The manufacturing method of claim 7, wherein said heating by said lamp is conducted intermittently.
